(19) United States
(12) Patent Application Publication
(10) Pub. No.: US 2018/0231295 A1
(43) Pub. Date: Aug. 16, 2018

(54) ELECTRONIC APPARATUS AND COOLING METHOD OF ELECTRONIC APPARATUS

(71) Applicant: FUJITSU LIMITED, Kawasaki-shi (JP)

(72) Inventors: YUSUKE AKIYAMA, Meguro (JP); Akira Okada, Kawasaki (JP); Kouichi Kuramitsu, Setagaya (JP); Hideaki MATSUMOTO, Yokohama (JP)

(73) Assignee: FUJITSU LIMITED, Kawasaki-shi (JP)

(21) Appl. No.: 15/886,920

(22) Filed: Feb. 2, 2018

(30) Foreign Application Priority Data
Feb. 13, 2017 (JP) 2017-023716

(51) Int. Cl. F25D 17/02; H05K 7/20; H01L 23/427; F28D 15/02

(52) U.S. Cl. CPC F25D 17/02; F28D 15/0275; H01L 23/427; H05K 7/20254

(57) ABSTRACT

An electronic apparatus includes a slot; a first electronic component which is inserted into the slot; a heat pipe coupled to the first electronic component; a first plate coupled to the heat pipe, and has a heat transferring face facing an insertion direction of the slot; a second plate which is provided in the slot, faces the first plate, and has a heat transferring face with which the first plate comes into contact; and a pipe coupled to the second plate, and in which refrigerant circulates.

### CROSS-REFERENCE TO RELATED APPLICATION

This application is based upon and claims the benefit of priority of the prior Japanese Patent Application No. 2017-23716, filed on Feb. 13, 2017, the entire contents of which are incorporated herein by reference.

### FIELD

The embodiments discussed herein are related to an electronic apparatus and a cooling method of the electronic apparatus.

### BACKGROUND

As a cooling technology of an electronic component which generates heat at a time of operation, a technology in which a cooling member such as a radiating fin, a cold plate, and a heat pipe is coupled to the electronic component is known.

Related to such a cooling technology, for example, a method in which one end of a cold plate coupled to an electronic component on a daughter board is inserted into a refrigerant duct which is provided on a mother board side coupled to the daughter board using a connector, and the electronic component coupled to the cold plate is cooled is known. In an electronic device to or from which a unit including an electronic component is inserted or extracted, a method in which a flat plate heat pipe extending from the unit in an insertion direction thereof is caused to be in surface contact with a heat absorbing plate on a main body side of the device, the heat absorbing plate being parallel to the flat plate heat pipe, by being partially overlapped, and heat transported to the heat absorbing plate is radiated by a radiator is known. As a related art, for example, Japanese Laid-open Utility Model Application Publication No. 63-167796, Japanese Laid-open Patent Publication No. 2001-156483, and the like, are disclosed.

Meanwhile, in a viewpoint of increasing cooling efficiency of the electronic component compared to a cooling method using a fan, or the like, a cooling method in which a pipe is disposed so as to pass through a position of an electronic component which generates heat at a time of operation, and refrigerant is caused to circulate in the pipe is known.

When such a cooling method in which refrigerant is used is adopted in cooling of an electronic component in a unit of an electronic apparatus to or from which the unit including the electronic component is inserted or extracted, for example, a structure in which a pipe on the side of the unit which is inserted or extracted and a pipe on the apparatus main body side may be attached or detached using a coupler is taken into consideration. However, when such a structure is adopted in the cooling method in which refrigerant is used, there is a high possibility that a risk such as leaking of the refrigerant or a pressure change may occur at a time of inserting or extracting of the unit (at time of inserting or extracting of the coupler). When considering the above situation, it is preferable to efficiently cool the electronic component in the unit which is inserted by using refrigerant, and suppressing the risk which is associated with the use of refrigerant.

### SUMMARY

According to an aspect of the invention, an electronic apparatus includes a slot; a first electronic component which is inserted into the slot; a heat pipe coupled to the first electronic component; a first plate coupled to the heat pipe, and has a heat transferring face facing an insertion direction of the slot; a second plate which is provided in the slot, faces the first plate, and has a heat transferring face with which the first plate comes into contact; and a pipe coupled to the second plate, and in which refrigerant circulates.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are diagrams which illustrate an example of electronic devices;

FIG. 2 is a diagram which illustrates an example of an electronic apparatus;

FIGS. 3A and 3B are explanatory diagrams of a refrigerant cooling method;

FIG. 4 is an explanatory diagram (explanatory diagram 1) of an example of an electronic apparatus in which the refrigerant cooling method is adopted;

FIGS. 5A and 5B are explanatory diagrams (explanatory diagrams 2) of an example of an electronic apparatus in which the refrigerant cooling method is adopted;

FIGS. 6A, 6B, and 6C are diagrams which illustrate an example of an electronic apparatus according to a first embodiment;

FIGS. 7A and 7B are explanatory diagrams (explanatory diagrams 1) of the electronic apparatus according to the first embodiment;

FIGS. 8A, 8B, and 8C are explanatory diagrams (explanatory diagrams 2) of the electronic apparatus according to the first embodiment;

FIGS. 9A and 9B are explanatory diagrams (explanatory diagrams 3) of the electronic apparatus according to the first embodiment;

FIGS. 10A and 10B are explanatory diagrams (explanatory diagrams 1) of an electronic apparatus according to a second embodiment;

FIGS. 11A, 11B, and 11C are explanatory diagrams (explanatory diagrams 2) of the electronic apparatus according to the second embodiment;

FIGS. 12A, 12B, and 12C are diagram which illustrate a modification example of a plate;

FIGS. 13A and 13B are explanatory diagrams (explanatory diagrams 1) of an electronic apparatus according to a third embodiment;

FIG. 14 is an explanatory diagram (explanatory diagram 2) of the electronic apparatus according to the third embodiment;

FIGS. 15A and 15B are explanatory diagrams (explanatory diagram 3) of the electronic apparatus according to the third embodiment;

FIGS. 16A and 16B are explanatory diagrams (explanatory diagrams 1) when detecting a plate connecting state according to the third embodiment;

FIGS. 17A and 17B are explanatory diagrams (explanatory diagrams 2) when detecting the plate connecting state according to the third embodiment;

FIG. 18 is a diagram which illustrates a flow of alarm generating processing according to the third embodiment; and

FIGS. 19A and 19B are diagrams which illustrate an example of an electronic apparatus according to a fourth embodiment.

### DESCRIPTION OF EMBODIMENTS

First, examples of an electronic device and an electronic apparatus are described.

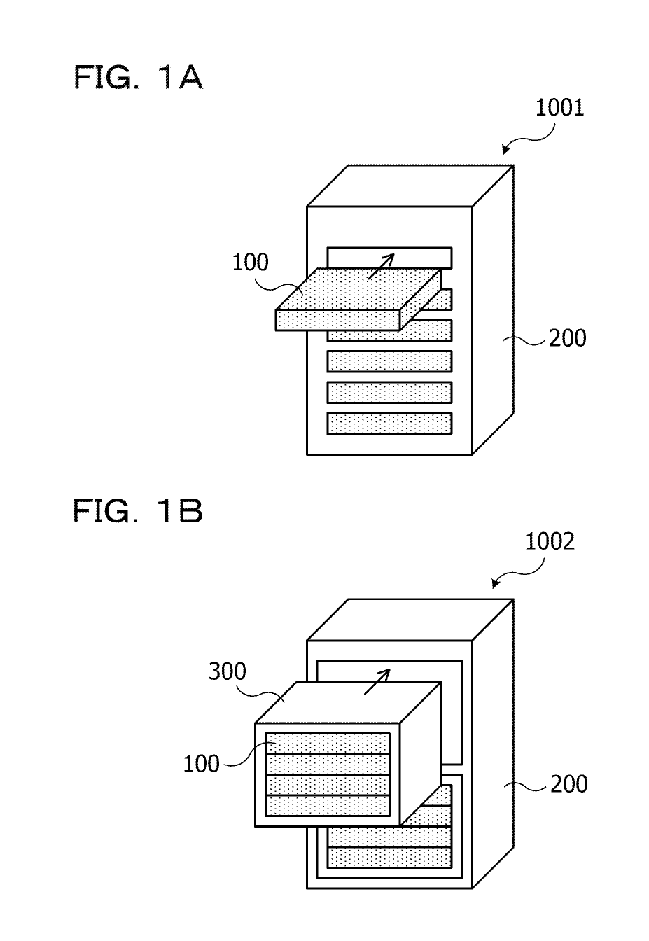

FIGS. 1A and 1B are diagrams which illustrate an example of the electronic device. FIGS. 1A and 1B schematically illustrate a perspective view of an example of the electronic device, respectively.

An electronic device 1001 illustrated in FIG. 1A has a structure in which a plurality of flat plate-shaped electronic apparatuses 100 are mounted on a rack 200 in a form of being stacked. An electronic device 1002 illustrated in FIG. 1B has a structure in which the plurality of flat plate-shaped electronic apparatuses 100 are accommodated in a housing 300, and the housing 300 is mounted on the rack 200 in a form of being stacked. A circuit board such as a mother board, and various electronic components such as a semiconductor device which is mounted thereon are included in the electronic apparatus 100 which is mounted on the electronic device 1001 or 1002. The electronic apparatus 100 is, for example, a communication device for performing communication processing.

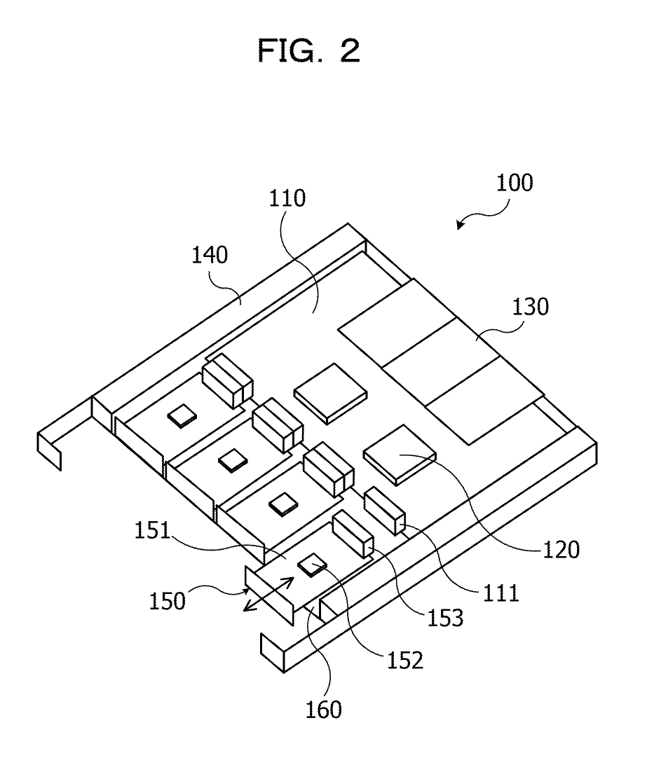

FIG. 2 is a diagram which illustrates an example of the electronic apparatus. FIG. 2 is a perspective view which schematically illustrates main portions of an example of the electronic apparatus.

The electronic apparatus 100 illustrated in FIG. 2 includes a mother board 110 (circuit board), an electronic component 120, and a fan unit 130.

A predetermined circuit pattern is provided in the mother board 110. Various electronic components 120 including the semiconductor device are mounted on the mother board 110 on which the predetermined circuit pattern is provided. The mother board 110 on which the electronic component 120 is mounted is accommodated in a housing 140 of the electronic apparatus 100.

The electronic component 120 on the mother board 110 generates heat along with an operation of the electronic apparatus 100. The fan unit 130 is provided with at least one fan which rotates so as to blow air to the electronic component 120 side, or intake air from the electronic component 120 side. The electronic component 120 on the mother board 110 which generates heat is cooled down (air cooling) by air blowing or air intake using such a fan unit 130. The fan unit 130 is provided at a rear portion of the electronic apparatus 100, for example, a portion on the rear face side of the above described rack 200 or a housing 300.

At least one slot 160 to or from which a plug-in unit (PIU) 150 may be inserted or extracted is provided at a portion at a front portion of the electronic apparatus 100, for example, a portion on a front side of the above described rack 200 or housing 300.

The plug-in unit 150 includes a circuit board 151, various electronic components 152 which are mounted on the circuit board 151, and a connector 153. The plug-in unit 150 is electrically coupled to the mother board 110 when the plug-in unit is inserted into the slot 160, and the connector 153 is coupled to a connector 111 which is provided in the mother board 110. When the plug-in unit 150 is electrically coupled to the mother board 110, the electronic apparatus 100 to which a predetermined function included in the plug-in unit 150 is added is obtained.

For example, the electronic device 1001 is realized (FIG. 1A) when the electronic apparatus 100 illustrated in FIG. 2 is mounted on the rack 200, as described above. Alternatively, the electronic device 1002 is realized (FIG. 1B) when the electronic apparatus 100 illustrated in FIG. 2 is accommodated in the housing 300, as described above, and the housing 300 is mounted on the rack 200.

Meanwhile, in the electronic apparatus 100, an electronic component 152 of the plug-in unit 150 which is inserted into the slot 160, and is electrically coupled to the mother board 110 generates heat along with an operation of the electronic apparatus 100. In the electronic apparatus 100, the electronic component 152 which generates heat is cooled down by air blowing or air intake using the fan unit 130, similarly to the electronic component 120 on the mother board 110.

However, when a heat generating amount of the electronic component 152 of each plug-in unit 150, or the number of mounted electronic components increases, or the number of plug-in units 150 which is inserted including the electronic component 152 which generates heat increases, cooling of the electronic component 152 may not be sufficiently performed in the fan unit 130. When cooling of the electronic component 152 is not sufficiently performed, there is a concern that overheating of the electronic component 152, a damage of the electronic component 152 due to that, and deterioration in performance of the electronic apparatus 100, and the electronic devices 1001 and 1002 on which the electronic apparatus is mounted may occur.

Meanwhile, as a method of cooling the electronic component which generate heat in the electronic apparatus, a cooling method using refrigerant, for example, an air cooling method in which liquid refrigerant is used is known, in addition to the air cooling method in which the above described fan is used. The cooling method using refrigerant has a merit in which cooling efficiency of the electronic component easily increases compared to the air cooling method.

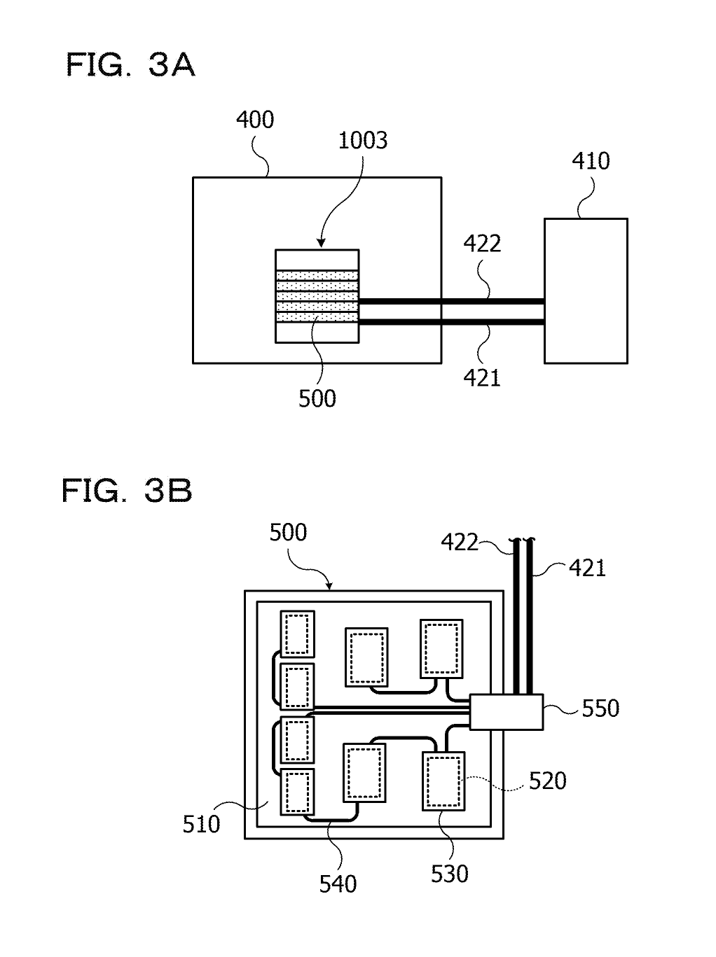

FIGS. 3A and 3B are explanatory diagrams of the cooling method using refrigerant. FIG. 3A illustrates an example of a cooling system in which the cooling method using refrigerant is adopted, and FIG. 3B schematically illustrates a plan view of main portions of an example of the electronic apparatus which is mounted on the electronic device in the cooling system.

An electronic device 1003 illustrated in FIG. 3A is a calculator such as a super computer, for example, and such an electronic device 1003 provided in a building 400, and a cooling tower 410 which is provided out of the building 400 are coupled, using a sending pipe 421 and a returning pipe 422 of refrigerant. The cooling tower 410 has a function of cooling a pump (not illustrated), and refrigerant at a fixed temperature. Refrigerant which is cooled down in the cooling tower 410 is sent to the electronic device 1003 through the sending pipe 421 using the pump, and is returned to the cooling tower 410 through the returning pipe 422 after circulating in the electronic device 1003.

As illustrated in FIG. 3B, an electronic apparatus 500 which is mounted on the electronic device 1003 includes a mother board 510 (circuit board), and various electronic components 520 such as a processor, a memory, and an interconnect controller which are mounted on the mother board 510. In the electronic apparatus 500, a cooling plate 530 is provided on the electronic component 520, and a pipe 540 is disposed so as to pass through the cooling plate 530 (position of electronic component 520). The pipe 540 which is disposed in the electronic apparatus 500 is coupled to the sending pipe 421 and the returning pipe 422 from the cooling tower 410 using a cooling module 550.

Refrigerant which is sent to the electronic apparatus 500 in the electronic device 1003 through the pipe 421 from the cooling tower 410 is circulated in the pipe 540, takes heat transmitted from the electronic component 520 to the cooling plate 530, and cools down the electronic component 520. The refrigerant which is circulated in the pipe 540 while taking heat of the cooling plate 530 (electronic component 520 under cooling plate) is returned to the cooling tower 410 through the returning pipe 421, is cooled down at a fixed temperature, and is sent to the electronic device 1003 (electronic apparatus 500 thereof) again through the returning pipe 422 thereafter. In the electronic device 1003, refrigerant is circulated in this manner, and the electronic component 520 of the electronic apparatus 500 is cooled down.

However, the electronic apparatus 500 is not configured so that a part of functions thereof is changed by the plug-in unit 150, like the above described electronic apparatus 100 (FIG. 2). When the electronic apparatus 500 is configured so that an operation thereof and a circulation of refrigerant may be stopped, it is possible to change a function when being exchanged to another electronic apparatus in a stopped state. However, when the electronic apparatus 500 is configured so that an operation thereof and a circulation of refrigerant may not be stopped, like a communication device which is operated all the time, it is not easy to change a part, or all of the functions in the structure of the above described electronic apparatus 500.

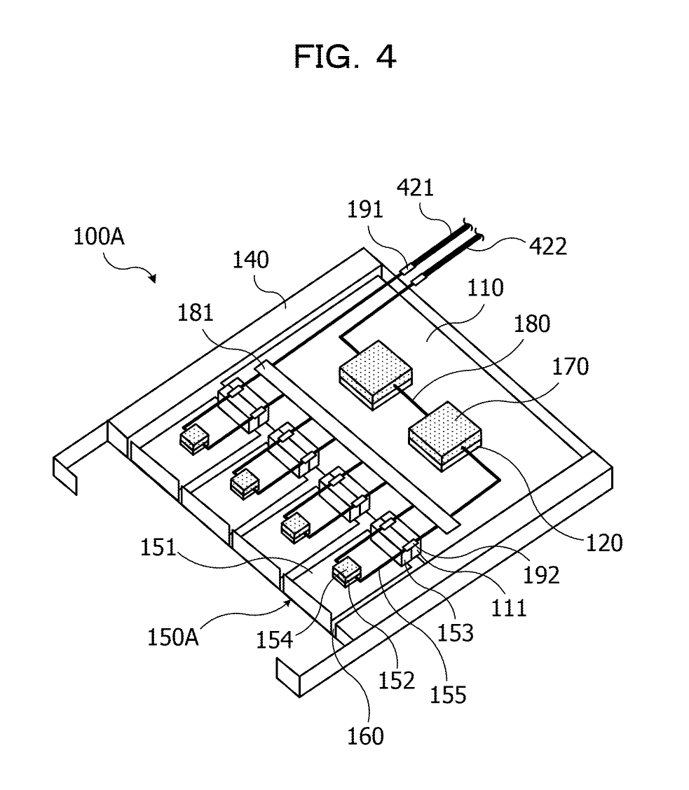

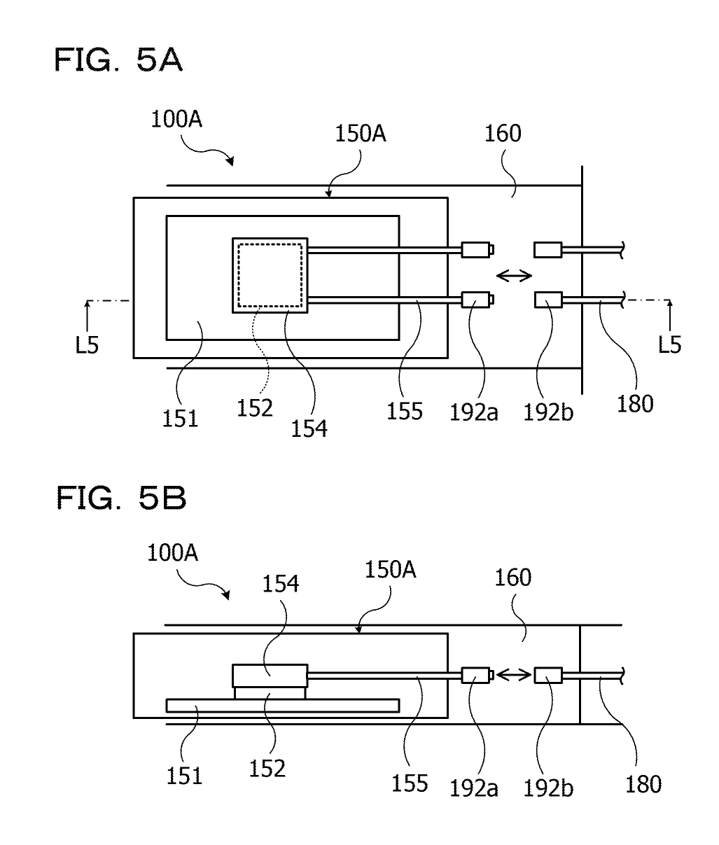

The cooling method using refrigerant is adopted in the electronic apparatus such as the communication device in which it is not possible to stop an operation and a circulation of refrigerant, and as the configuration in which a function may be changed without stopping thereof, for example, electronic apparatuses which are illustrated in FIGS. 4, 5A, and 5B may be taken into consideration.

FIGS. 4, 5A, and 5B are explanatory diagrams of an example of an electronic apparatus in which the cooling method using refrigerant is adopted. FIG. 4 is a schematic perspective view of main portions of an example of an electronic apparatus in which the cooling method using refrigerant is adopted. FIG. 5A is a planar schematic view of main portions of an example of a plug-in unit which is inserted or extracted with respect to an electronic apparatus. FIG. 5B illustrates a sectional schematic view of main portions of an example of the plug-in unit which is inserted or extracted with respect to the electronic apparatus. FIG. 5B is a sectional schematic view taken along line L5-L5 in FIG. 5A. In FIGS. 5A and 5B, an illustration of a connector connection portion between a plug-in unit and a mother board is omitted for convenience.

An electronic apparatus 100A illustrated in FIG. 4 includes a housing 140, a mother board 110 accommodated in the housing 140, an electronic component 120 which is mounted on the mother board 110, a connector 111, and a slot 160 to or from which a plug-in unit 150A is inserted or extracted. When the plug-in unit 150A is inserted into the slot 160, a function of the electronic apparatus 100A is changed.

In the electronic apparatus 100A in which the cooling method using refrigerant is adopted, a cooling plate 170 is provided on the electronic component 120 which is mounted on the mother board 110, and a pipe 180 is disposed so as to pass through the cooling plate 170 (position of electronic component 120). The pipe 180 which is disposed in the electronic apparatus 100A connects a portion between an electronic device on which the electronic apparatus 100A is mounted and a cooling tower (not illustrated) and is coupled to the sending pipe 421 and the returning pipe 422 of refrigerant. For example, a connection of the pipe 180 of the electronic apparatus 100A, and the sending pipe 421 and the returning pipe 422 is performed, using a coupler (coupler connection portion 191).

A circuit board 151, various electronic components 152 mounted on the circuit board 151, and a connector 153 is included in the plug-in unit 150A. In addition, in the plug-in unit 150A, a cooling plate 154 is provided on the electronic component 152 which is mounted on the circuit board 151, and a pipe 155 is disposed so as to pass through the cooling plate 154 (position of electronic component 152). The pipe 155 of the plug-in unit 150A is coupled to the pipe 180 of the electronic apparatus 100A using a coupler (coupler connection portion 192). A switcher 181 of a refrigerant flow path is provided in the pipe 180 of the electronic apparatus 100A, for example.

As illustrated in FIGS. 4, 5A and 5B, the plug-in unit 150A is inserted into the slot 160 of the electronic apparatus 100A.

At this time, as illustrated in FIG. 4, the connector 153 of the plug-in unit 150A which is inserted is coupled to the connector 111 of the mother board 110, and the plug-in unit 150A and the mother board 110 (and electronic component 120 mounted thereon) are electrically coupled. In addition, as illustrated in FIGS. 5A and 5B, a coupler 192a of the pipe 155 of the plug-in unit 150A which is inserted, and a coupler 192b of the pipe 180 of the electronic apparatus 100A are coupled. In this manner, a refrigerant flow path through which refrigerant flows from the pipe 180 of the electronic apparatus 100A is formed in the pipe 155 of the plug-in unit 150A.

When extracting the plug-in unit 150A which is inserted from the slot 160, the connector 153 is detached from the connector 111, the coupler 192a is detached from the coupler 192b, and the plug-in unit 150A is extracted along the slot 160.

In the electronic apparatus 100A with the above described configuration, it is possible to perform inserting or extracting of the respective plug-in units 150A, and a change in function of the electronic apparatus 100A using thereof, without stopping an operation of the electronic apparatus 100A and a circulation of refrigerant, by adjusting the refrigerant flow path in the switcher 181.

However, in such an electronic apparatus 100A, there is a possibility that the following problem may occur.

For example, in the electronic apparatus 100A, there is a risk that refrigerant leaks in the coupler connection portion 192 (couplers 192a and 192b) when inserting or extracting the plug-in unit 150A, or when refrigerant is circulating between the pipe 155 of the plug-in unit 150A and the pipe 180 of the electronic apparatus 100A. There is a concern that a cost of the electronic apparatus 100A and the electronic device on which the electronic apparatus is mounted may increase when providing an absorbing material which absorbs refrigerant, or a sensor for detecting leaking of refrigerant at the periphery of the coupler connection portion 192, in preparation for leaking of refrigerant.

In the electronic apparatus 100A, refrigerant flows into the pipe 155 of the plug-in unit 150A from the pipe 180 of the electronic apparatus 100A when inserting the plug-in unit 150A (when connecting couplers 192a and 192b). For this reason, there is a risk that a pressure of refrigerant which circulates in the refrigerant flow path (pipes 180 and 155) of the electronic apparatus 100A is reduced. The larger the number of plug-in units 150A which is inserted, the smaller the pressure of the refrigerant. When the pressure of refrigerant decreases, a flow rate (flow speed) of the refrigerant decreases, and there is a concern that overheating of the electronic component 120 on the mother board 110, or the electronic component 152 of the plug-in unit 150A, and a damage due to overheating, and deterioration in performance of the electronic apparatus 100A and the electronic device on which the electronic apparatus is mounted may occur.

In the electronic apparatus 100A, refrigerant may remain in the pipe 155 of the plug-in unit 150A which is extracted. For this reason, there is a risk that the refrigerant remaining in the pipe 155 of the plug-in unit 150A which is extracted leaks out. In addition, the refrigerant remaining in the pipe 155 is liquid containing water, and when the plug-in unit 150A is placed in an environment in which the refrigerant freezes (high place, or the like), there is a risk that a volume of the remaining refrigerant expands when freezing, and causes the pipe 155 to be broken. It is also possible to take out refrigerant which remains in the pipe 155 every time, after extracting or before inserting of the plug-in unit 150A; however, there is a concern that a work of inserting or extracting the plug-in unit 150A may become complicated. There is also a concern that it is desirable to manage or dispose the extracted refrigerant, or a cost thereof may occur depending on a type of the refrigerant.

Since the couplers 192a and 192b are used in the electronic apparatus 100A in order to insert or extract the plug-in unit 150A in which refrigerant is circulated, there is a case in which a cost increases due to that.

By taking into consideration such a problem, hereinafter, a configuration in the following embodiment is adopted, and an electronic component of the plug-in unit which is inserted into an electronic apparatus in which the cooling method using refrigerant is adopted is cooled down.

First, a first embodiment is described.

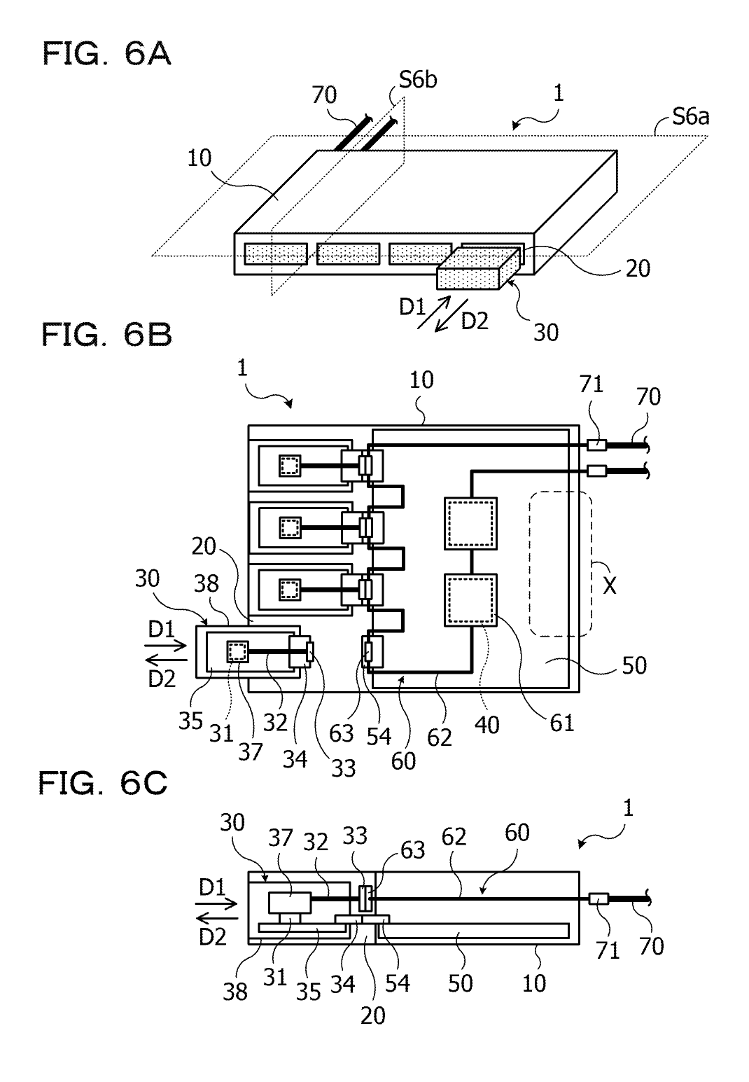

FIGS. 6A, 6B, and 6C are diagrams which illustrate an example of an electronic apparatus according to the first embodiment. FIG. 6A schematically illustrates a perspective view of main portions of the example of the electronic apparatus. FIG. 6B illustrates a planar schematic view of main portions of the example of the electronic apparatus. FIG. 6C illustrates a sectional schematic view of main portions of the example of the electronic apparatus. FIG. 6B illustrates a planar schematic view of S6a in FIG. 6A, and FIG. 6C illustrates a sectional schematic view of S6b in FIG. 6A.

An electronic apparatus 1 illustrated in FIGS. 6A to 6C includes a housing 10, and a slot 20 which extends toward the inside from the surface of the housing 10. A plurality of the slots 20 are exemplified here. A plug-in unit 30 is inserted into the slot 20 in a depth direction (inserting direction) D1 thereof, and the inserted plug-in unit 30 is extracted in an opposite direction (extracting direction) D2.

As illustrated in FIGS. 6B and 6C, a mother board 50 (circuit board) on which the electronic component 40 is mounted, and a cooling unit using refrigerant 60 are provided in the housing 10 of the electronic apparatus 1.

A predetermined circuit pattern is provided in the mother board 50. Various electronic components 40 including a semiconductor device such as a processor or a memory are mounted on the mother board 50 in which the predetermined circuit pattern is provided. Here, as the electronic components 40 which are mounted on the mother board 50, two electronic components 40 which generate heat along with an operation are exemplified.

The cooling unit using refrigerant 60 includes a cooling plate 61 which is provided on the electronic component 40, a pipe 62 which is disposed so as to pass through the cooling plate 61 (position of electronic component 40), and a heat transferring plate 63 which is located inside the slot 20 by being coupled to the pipe 62. The plate 63 of the cooling unit using refrigerant 60 is provided so that a heat conductive face thereof faces the plug-in unit 30 side which is inserted or extracted with respect to the slot 20. A refrigerant pipe 70 (sending pipe and returning pipe) which is coupled to a cooling tower is coupled to a pipe 62 of the cooling unit using refrigerant 60 using a coupler 71 (FIGS. 6B and 6C), and refrigerant (for example, liquid refrigerant) is circulated through the refrigerant pipe 70.

In the housing 10 of the electronic apparatus 1, like the X portion in FIG. 6B, for example, a fan unit including a fan may be provided at a rear portion (rack on which electronic apparatus 1 is mounted, or portion as rear face side of housing) of the electronic apparatus 1. In this manner, a hybrid cooling method of refrigerant cooling using the cooling unit using refrigerant 60, and cooling using air blowing or air intake of a fan unit (air cooling) may be adopted in the electronic apparatus 1.

As illustrated in FIGS. 6B and 6C, the plug-in unit 30 which is inserted or extracted with respect to the slot 20 includes an electronic component 31 which is mounted on the circuit board 35, and generates heat along with an operation in the inside thereof. As illustrated in FIGS. 6B and 6C, the plug-in unit 30 further includes a heat pipe 32 which is coupled to the electronic component 31 in the inside through the cooling plate 37, and the heat conductive plate 33 which is coupled to the heat pipe 32. The plate 33 is provided so that a heat conductive face thereof faces the inserting direction D1 of the plug-in unit 30 toward the slot 20.

The plate 33 of the plug-in unit 30 which is inserted into the slot 20 is caused to come into contact with a heat conductive face of the plate 63 of the cooling unit using refrigerant 60 which is provided in the slot 20 by facing the plate 33. The plug-in unit 30 and the cooling unit using refrigerant 60 are thermally coupled when the plate 33 and the plate 63 come into contact with each other in this manner.

As illustrated in FIG. 6C, in the plug-in unit 30, a connector 34 is provided in the circuit board 35 on which the electronic component 31 is mounted. As illustrated in FIGS. 6B and 6C, the connector 34 of the plug-in unit 30 which is inserted into the slot 20 is coupled to a connector 54 which is provided in the mother board 50. The plug-in unit 30 and the mother board 50 are electrically coupled when the connector 34 and the connector 54 are coupled to each other in this manner.

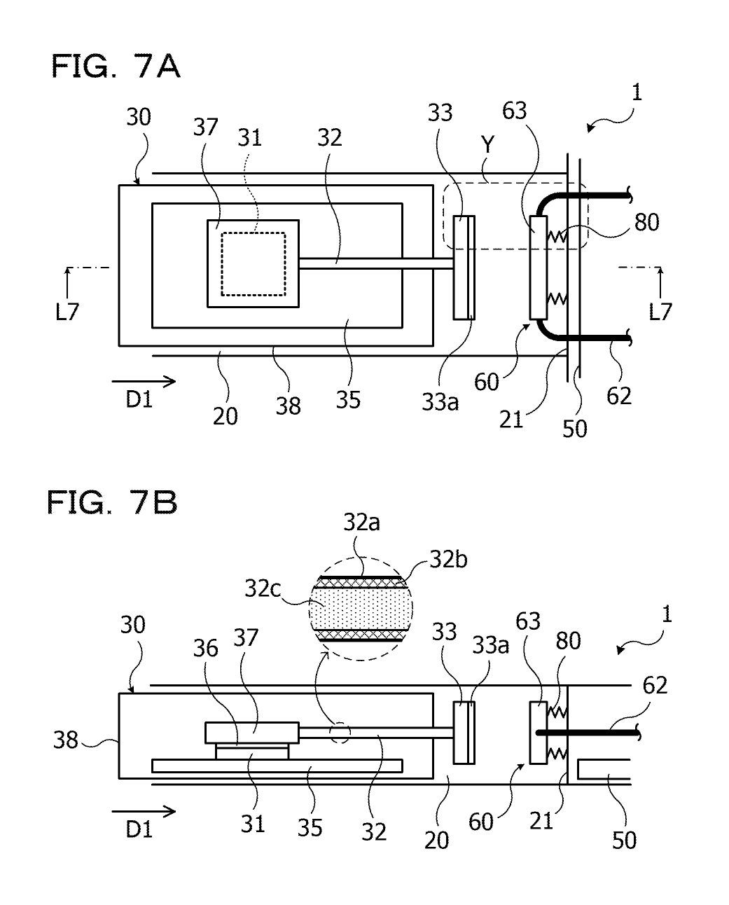

The plug-in unit 30, and inserting thereof into the slot 20 in the above described electronic apparatus 1 are further described with reference to FIGS. 7A to 9B.

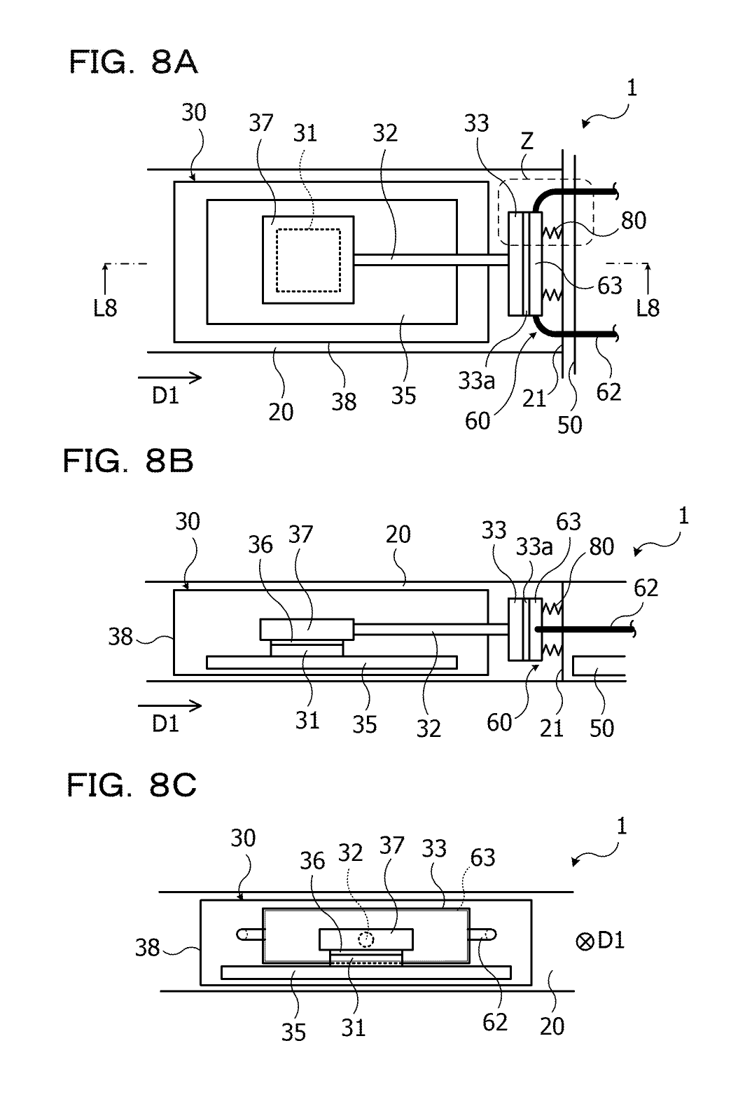

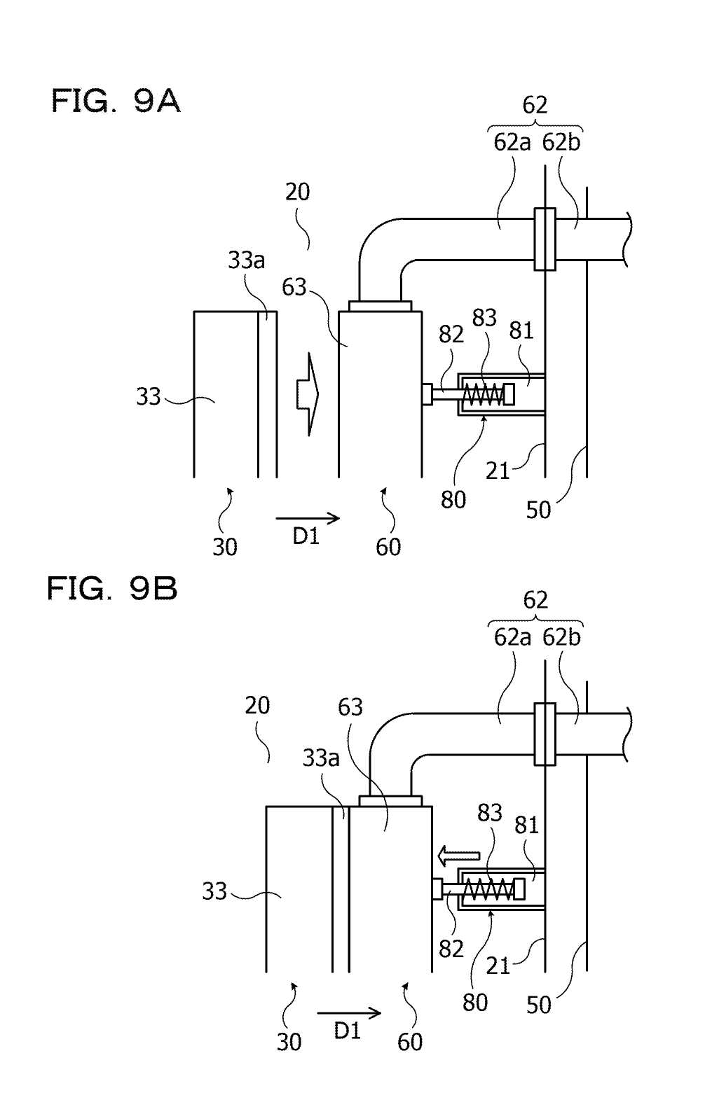

FIGS. 7A, 7B, 8A, 8B, 8C, 9A, and 9B are explanatory diagrams of the electronic apparatus according to the first embodiment. FIG. 7A is a planar schematic view of main portions when the plug-in unit is inserted. FIG. 7B is a sectional schematic view of main portions when the plug-in unit is inserted. FIG. 8A is a planar schematic view of main portions after inserting the plug-in unit. FIG. 8B is a sectional schematic view of main portions after inserting the plug-in unit. FIG. 8C is a front schematic view of main portions which is viewed from the slot side after inserting the plug-in unit. FIG. 9A is a partially enlarged schematic view when inserting the plug-in unit. FIG. 9B is partially enlarged schematic view after inserting the plug-in unit. FIG. 7B is a sectional schematic view which is taken along line L7-L7 in FIG. 7A. FIG. 8B is a sectional schematic view which is taken along line L8-L8 in FIG. 8A. FIG. 9A is an enlarged schematic view of a Y portion in FIG. 7A. FIG. 9B is an enlarged schematic view of a Z portion in FIG. 8A. In FIGS. 7A, 7B, and 8A to 8C, a connector connection portion between the plug-in unit and the mother board is not illustrated for convenience.

As illustrated in FIGS. 7A and 7B, the plug-in unit 30 includes the electronic component 31, the heat pipe 32, and the plate 33.

The electronic component 31 is various electronic components such as a semiconductor device which generates heat along with an operation. Such an electronic component 31 is mounted on the circuit board 35 such as a printed circuit board. Here, for convenience, one electronic component 31 mounted on the circuit board 35 is exemplified; however, a plurality of the electronic components 31 may be mounted on the circuit board 35.

A cooling plate 37 with high heat conductivity in which metal such as copper or aluminum is used is provided on the electronic component 31, directly, or through a thermal interface member 36a such as a thermal sheet or thermal grease which is illustrated in FIG. 7B. The heat pipe 32 is provided so as to extend from the cooling plate 37 toward the inserting direction D1 of the plug-in unit 30.

The heat pipe 32 includes a pipe 32a with high heat conductivity in which metal such as copper or aluminum is used, a wick 32b which is provided in the pipe 32a (for example, inner wall), and hydraulic liquid (or, vapor thereof) 32c such as water which is provided in the pipe 32a. One end portion of the heat pipe 32 is, for example, coupled to the cooling plate 37, or is disposed so as to run through the inside of the cooling plate 37. The heat pipe 32 may be coupled to the cooling plate 37, by setting the cooling plate 37 to a flat plate-shaped heat pipe structure.

The circuit board 35, the electronic component 31 which is mounted on the circuit board, the cooling plate 37 provided thereon, and a part of the heat pipe 32 which extends therefrom are accommodated in a housing 38 of the plug-in unit 30. The heat pipe 32 extends from the inside of the housing 38 to the outer side thereof, and the plate 33 is provided at a tip end portion of the heat pipe 32 which extends to the outer side of the housing 38.

The plate 33 is provided at the tip end portion of the heat pipe 32 so as to face the inserting direction D1 of the plug-in unit 30. A material with high heat conductivity such as metal of copper or aluminum is used in the plate 33. As illustrated in FIGS. 7A and 7B, a thermal sheet, or a thermal interface member 33a such as thermal grease may be provided on the side of the plate 33 which faces the inserting direction D1. A tip end portion of the heat pipe 32 is coupled to the plate 33, for example, or is disposed so as to run through the inside of the plate 33. Alternatively, the heat pipe 32 may be coupled to the plate 33, by setting the plate 33 to a flat plate-shaped heat pipe structure.

As illustrated in FIGS. 7A and 7B, a plate 63 of the cooling unit using refrigerant 60 which faces the plate 33 of the plug-in unit 30 is provided in the slot 20 into which the plug-in unit 30 is inserted. A material with high heat conductivity such as metal of copper or aluminum is used in the plate 63. As described above, the pipe 62 which is disposed so as to pass through the position of the electronic component 40 on the mother board 50 by being coupled to the refrigerant pipe 70 is coupled to the plate 63 (FIG. 6B). A refrigerant flow path which communicates with the pipe 62 is provided in the plate 63. Refrigerant which circulates in the pipe 62 circulates the refrigerant flow path in the plate 63 by entering from the pipe 62 which is coupled to an entrance of the refrigerant flow path of the plate 63, and is extracted from the pipe 62 which is coupled to an exit of the refrigerant flow path of the plate 63.

As illustrated in FIG. 9A, the pipe 62 of the cooling unit using refrigerant 60 is set to a connecting structure of a portion 62a which is directly coupled to the plate 63 by being provided on the slot 20 side and a portion 62b on the mother board 50 side on the depth side of an end 21 (slot end) of the slot 20. A material with elasticity in the inserting or extracting direction (inserting direction D1 and opposite direction thereof) of the plug-in unit 30 is used in the portion 62a on the slot 20 side of the pipe 62. For example, an FEP (tetrafluoroethylene-hexafluoropropylene copolymer) tube is used in the portion 62a on the slot 20 side of the pipe 62. For example, a material of metal, or the like, such as copper or aluminum is used in the portion 62b on the mother board 50 side which is coupled to such a portion 62a of the pipe 62. In addition, a material such as FEP may be used in the portion 62b, similarly to the portion 62a.

A damper 80 (urging portion) is provided between the plate 63 to which the elastic portion 62a of the pipe 62 is coupled and the slot end 21. As illustrated in FIG. 9A, the damper 80 includes a cylinder 81 which is fixed to the slot end 21, a piston rod 82 of which one end side is fixed to the plate 63, and the other end side extends to the inside of the cylinder 81, and a spring 83 which is provided at a portion in the cylinder 81 of the piston rod 82. The plate 63 is urged to the plug-in unit 30 (plate 33 thereof) side, which is inserted into the slot 20, by the damper 80.

In this manner, the plate 63 of the cooling unit using refrigerant 60 has a floating structure by the portion 62a of the pipe 62 which has elasticity in the inserting or extracting direction (inserting direction D1 and opposite direction thereof) of the plug-in unit 30, and the damper 80 which urges thereof to the plug-in unit 30 side.

As illustrated in FIGS. 7A, 7B, and 9A, the plug-in unit 30 is inserted into the slot 20 so that the plate 33 thereof faces the inserting direction D1 in the slot 20 (illustrated using thick arrow in FIG. 9A). The connector 34 of the plug-in unit 30 inserted into the slot 20 is coupled to the connector 54 of the mother board 50, as described above (FIGS. 6B and 6C). In the plug-in unit 30 which is inserted into the slot 20, the connector 34 thereof is coupled to the connector 54 of the mother board 50. In addition, for example, as illustrated in FIGS. 8A, 8B, and 9B, the plate 33 thereof (thermal interface member 33a on surface thereof) comes into contact with the plate 63 of the cooling unit using refrigerant 60.

At this time, the plate 63 of the cooling unit using refrigerant 60 is pressed to the slot end 21 side (mother board 50 side) by the plate 33 of the plug-in unit 30 which is inserted into the slot 20. In the plate 63 of the cooling unit using refrigerant 60, an initial position before the plug-in unit 30 is inserted is set so as to be pressed by the plate 33 of the plug-in unit 30 which is inserted into the slot 20 in this manner. In the portion 62a of the pipe 62 which is coupled to the plate 63 of the cooling unit using refrigerant 60 on the slot 20 side, a material such as FEP which has elasticity in the inserting direction D1 (and opposite direction thereof) of the plug-in unit 30. In this manner, it is possible to press the plate 63 of the cooling unit using refrigerant 60 using such a plate 33 of the plug-in unit 30.

The plate 63 of the cooling unit using refrigerant 60 which is pressed by the plate 33 of the plug-in unit 30 is urged to the plate 33 side of the plug-in unit 30 using the damper 80, as illustrated in FIG. 9B (illustrated by thick arrow in FIG. 9B). When setting an urging structure in which the plate 63 which is pressed by the plate 33 is urged by the damper 80 in this manner, even when there is tolerance in one side or both sides of the plug-in unit 30 and the cooling unit using refrigerant 60, the tolerance is absorbed.

As illustrated in FIG. 9B, when setting the urging structure in which the plate 63 pressed by the plate 33 is urged by the damper 80, absorbing of the tolerance is attained, and the plate 33 of the plug-in unit 30 and the plate 63 of the cooling unit using refrigerant 60 come into press contact. In this manner, the electronic apparatus 1 illustrated in FIGS. 8A to 8C in which the plate 33 of the plug-in unit 30 which is inserted into the slot 20 and the plate 63 of the cooling unit using refrigerant 60 which is provided in the slot 20 come into contact is obtained.

As illustrated in FIGS. 6A, 6B, 6C, 7A, 7B, 8A, 8B, 8C, 9A, and 9B, in the electronic apparatus 1 in which the plug-in unit 30 is inserted, for example, the electronic component 40 mounted on the mother board 50 and the electronic component 31 mounted on the circuit board 35 of the plug-in unit 30 may generate heat.

In this case, heat generated by the electronic component 40 on the mother board 50 is transmitted to the cooling plate 61 of the cooling unit using refrigerant 60, which is provided on the electronic component 40. The heat transmitted to the cooling plate 61 from the electronic component 40 is removed by refrigerant which is circulated in the pipe 62 which is provided so as to pass through the cooling plate 61. In this manner, the electronic component 40 on the mother board 50 is cooled down, and overheating of the electronic component 40, and a damage due to the overheating are suppressed. When overheating and a damage of the electronic component 40 are suppressed, deterioration in performance of the electronic apparatus 1 including the electronic component 40, and the electronic device on which the electronic component is mounted, which is caused by the damage of the electronic component 40, are suppressed.

The refrigerant which is circulated in the pipe 62 of the cooling unit using refrigerant 60 is circulated in the plate 63 which is located in the slot 20. The plate 33 of the plug-in unit 30 which is inserted into the slot 20 comes into contact with the plate 63 in which the refrigerant is circulated. Heat generated in the electronic component 31 on the circuit board 35, of the plug-in unit 30 in the slot 20 is transmitted to the cooling plate 37 through the thermal interface member 36. In this manner, a connection portion side of the heat pipe 32 with respect to the cooling plate 37 becomes a relatively high temperature due to the heat from the electronic component 31. In addition, the connection portion side with respect to the plate 33 becomes a relatively low temperature by coming into contact with the plate 63 in which refrigerant is circulated.

The hydraulic liquid 32c in the pipe 32a is vaporized on the connection portion side with the cooling plate 37 in which a temperature of the heat pipe 32 becomes relatively high. Vapor of the hydraulic liquid 32c moves to the connection portion side with the plate 33 of the heat pipe 32 with a relatively low temperature, in the pipe 32a, and is condensed by being cooled down. The condensed hydraulic liquid 32c moves to the connection portion side with the cooling plate 37 of the heat pipe 32 of which a temperature is relatively high, through the wick 32b, and is vaporized by being heated by heat from the electronic component 31.

Due to such a heat transmitting cycle of the heat pipe 32, heat of the electronic component 31 on the circuit board 35 is removed by refrigerant which is circulated in the pipe 62 through the cooling plate 37, the heat pipe 32, the plate 33, and the plate 63. In this manner, the electronic component 31 of the plug-in unit 30 is cooled down, and overheating of the electronic component 31, and damage due to overheating of the electronic component 31 are suppressed. When overheating and damage of the electronic component 31 are suppressed, deterioration in performance of the plug-in unit 30 including the electronic component 31, the electronic apparatus 1 on which the plug-in unit 30 is mounted, and the electronic device on which such an electronic apparatus 1 is mounted is suppressed.

According to the above described electronic apparatus 1, it is possible to cool down the electronic component 40 which is mounted on the mother board 50, and generates heat, and the electronic component 31 which is mounted on the circuit board 35 of the plug-in unit 30 which is inserted, and generates heat using the cooling unit using refrigerant 60 in which refrigerant is used. In this manner, it is possible to obtain the electronic apparatus 1 with excellent performance, and great reliability.

In the electronic apparatus 1, the cooling unit using refrigerant 60 in which refrigerant is used and the plug-in unit 30 which is inserted into the slot 20 are thermally coupled by causing the plate 63 which is coupled to the pipe 62 in which refrigerant is circulated and the plate 33 which is coupled to the heat pipe 32 to come into contact with each other.

A pipe in which refrigerant is circulated is not provided in the plug-in unit 30 which is inserted into the slot 20, and a coupler connection portion (coupler connection portion 192 exemplified in FIGS. 4 to 5B) with the pipe 62 which is used in cooling of the electronic component 40 on the mother board 50 is not provided. When the plug-in unit 30 is separated from the refrigerant flow path of the cooling unit using refrigerant 60, it is possible to suppress a risk of leaking of refrigerant in the plug-in unit 30, and leaking of refrigerant in the coupler connection portion. It is not desirable to provide an absorbing material which absorbs leaked refrigerant, or a sensor for detecting leaking of refrigerant in preparation for leaking of refrigerant. For this reason, it is possible to obtain the plug-in unit 30 and the electronic apparatus 1 at a low cost. The coupler is not used when connecting the cooling unit using refrigerant 60 and the plug-in unit 30. For this reason, it is also possible to obtain the plug-in unit 30 and the electronic apparatus 1 at a low cost.

In addition, since the pipe in which refrigerant is circulated is not provided, and the coupler connection portion is not provided in the plug-in unit 30, a coupler connecting job when inserting the plug-in unit 30 is not desirable. In addition, it is possible to suppress a change in pressure of refrigerant when connecting the coupler, and a change in cooling performance due to the change in pressure. Also the work of extracting refrigerant remaining in the pipe is not desirable, after extracting the plug-in unit 30. For this reason, it is possible to reduce a complexity of the work of inserting or extracting the plug-in unit 30, and suppress the work of managing or disposing extracted refrigerant, and an increase in cost which is associated therewith.

In the electronic apparatus 1, the plate 63 of the cooling unit using refrigerant 60 is set to a floating structure in which the plate 63 is pressed by the plate 33 of the plug-in unit 30 which is inserted into the slot 20, and an urging structure in which the pressed plate 63 is urged to the plate 33 side by the damper 80. In this manner, it is possible to absorb a tolerance which may present in one, or both of the cooling unit using refrigerant 60 and the plug-in unit 30. In addition, it is possible to increase heat transferring efficiency between the cooling unit using refrigerant 60 and the plug-in unit 30 by causing the plate 63 and the plate 33 to come into contact with each other.

Subsequently, a second embodiment is described.

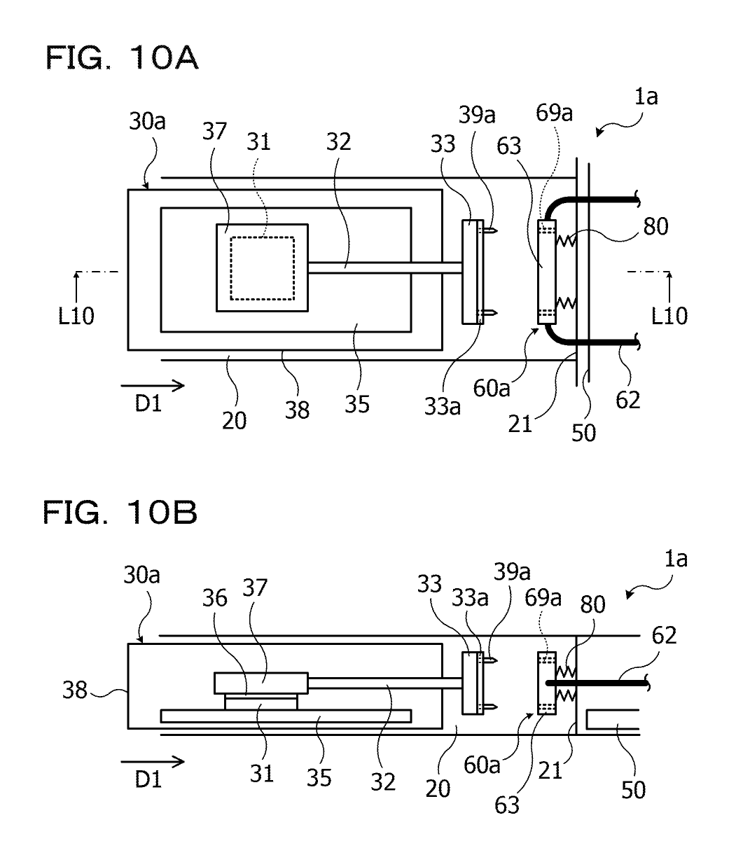

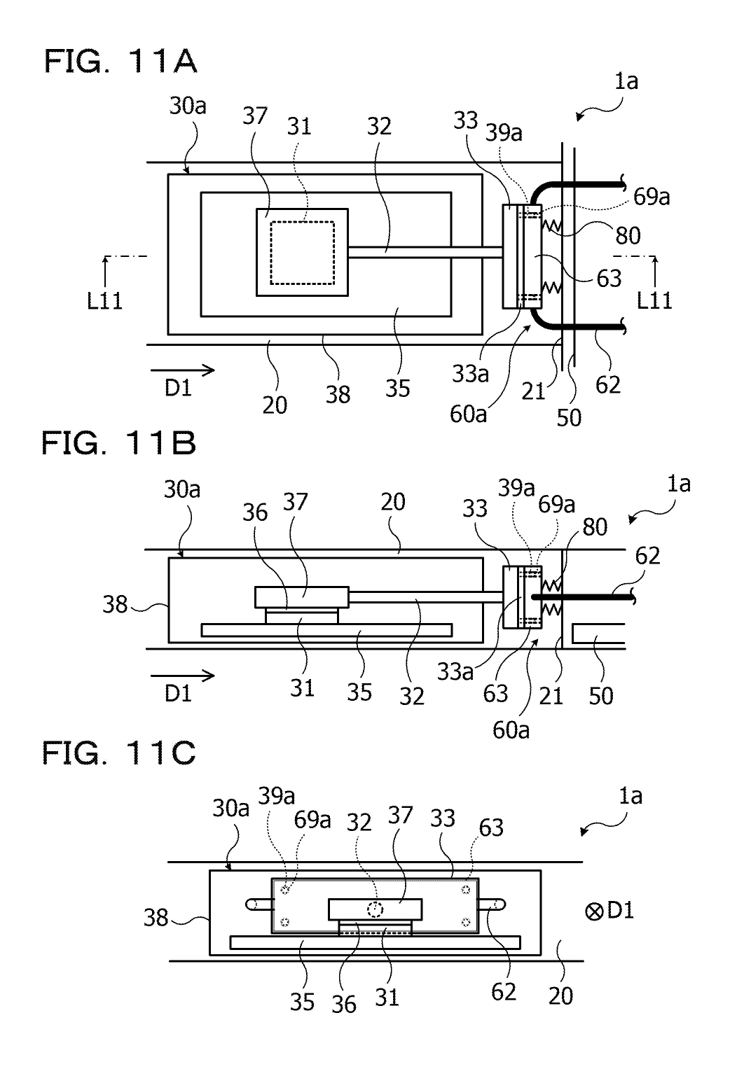

FIGS. 10A, 10B, 11A, 11B, and 11C are explanatory diagrams of an electronic apparatus according to the second embodiment. FIG. 10A is a planar schematic view of main portions when inserting the plug-in unit. FIG. 10B is a sectional schematic view of main portions when inserting the plug-in unit. FIG. 11A is a planar schematic view of main portions after inserting the plug-in unit. FIG. 11B is a sectional schematic view of main portions after inserting the plug-in unit. FIG. 11C is a front schematic view of main portions which is viewed from the slot side after inserting the plug-in unit. FIG. 10B is a sectional schematic view which is taken along line L10-L10 in FIG. 10A. FIG. 11B is a sectional schematic view which is taken along line L11-L11 in FIG. 11A. In FIGS. 10A, 10B, and 11A to 11C, the coupler connection portion between the plug-in unit and the mother board is not illustrated, for convenience.

A plug-in unit 30a which is illustrated in FIGS. 10A and 10B is different from the plug-in unit 30 in a point that a pin 39a protruding in the inserting direction D1 toward the slot 20 is provided in a plate 33 thereof. A cooling unit using refrigerant 60a which is illustrated in FIGS. 10A and 10B is different from the cooling unit using refrigerant 60 in a point that a hole 69a into which the pin 39a is inserted is provided at a position of the plate 63, corresponding to the pin 39a of the plug-in unit 30a.

In the plug-in unit 30a and the cooling unit using refrigerant 60a, the plate 33 and the plate 63 face each other by suppressing a gap therebetween, when the pin 39a is inserted into the corresponding hole 69a.

In FIGS. 10A and 10B (and FIGS. 11A and 11C), as an example, the plug-in unit 30a in which four pins 39a are provided in the plate 33, and the cooling unit using refrigerant 60a in which four holes 69a are provided in the plate 63 are illustrated. The number of pins 39a and the holes 69a are not limited to these. It is possible to provide at least one pin 39a in the plate 33, and provide at least one hole 69a in the plate 63.

As illustrated in FIGS. 10A and 10B, the plate 33 of the plug-in unit 30a is inserted into the slot 20 in the inserting direction D1 toward the slot 20. At this time, in the plug-in unit 30a, when a tip end of the pin 39a of the plate 33 is inserted into the hole 69a of the plate 63 of the cooling unit using refrigerant 60a, the pin 39a is guided by the hole 69a, and is inserted into the slot 20. In addition, for example, as illustrated in FIGS. 11A to 11C, the plate 33 (thermal interface member 33a on surface thereof) of the plug-in unit comes into contact with the plate 63 of the cooling unit using refrigerant 60a, in a state in which the pin 39a is inserted into the hole 69a.

At this time, the plate 63 of the cooling unit using refrigerant 60a is pressed by the plate 33 of the plug-in unit 30a. Then, the plate 63 is urged to the plate 33 side of the plug-in unit 30a due to the damper 80. In this manner, a tolerance which may be present in the cooling unit using refrigerant 60a and the plug-in unit 30a is absorbed, and an electronic apparatus 1a which is illustrated in FIGS. 11A to 11C in which the plate 63 and the plate 33 come into contact with each other is obtained.

In the electronic apparatus 1a, a gap between the plate 33 and the plate 63 is efficiently suppressed when the pin 39a of the plate 33 of the plug-in unit 30a which is inserted into the slot 20 is inserted into the hole 69a of the plate 63 of the cooling unit using refrigerant 60a.

For example, when one of the plate of the plug-in unit which is inserted into the slot and the plate of the cooling unit using refrigerant which is coupled thereto is coupled to the other in an inclined state, or only one of both is coupled, a coupled area between plates decreases. When the plug-in unit is operated in such a connection state, cooling efficiency of an electronic component which is mounted thereon, and generates heat decreases. When the cooling efficiency decreases, and overheating of the electronic component occurs, there is a high risk that the electronic component is damaged, or an operation of the plug-in unit on which the electronic component is mounted or the electronic apparatus into which the plug-in unit is inserted is stopped. When the electronic apparatus is a communication device which is operated all the time, it is desirable to avoid such a risk of stopping the operation of the plug-in unit or the electronic apparatus as much as possible. When a hybrid cooling method of cooling using refrigerant in which the cooling unit using refrigerant is used, and air cooling in which the fan unit is used is adopted in the electronic apparatus, for example, the number of rotations of the fan is suppressed based on a temperature of the electronic component or the plug-in unit on which the electronic component is mounted. In such an electronic apparatus, the number of rotations of the fan increases associated with a temperature rise of the electronic component or the plug-in unit, and there is a possibility of causing an increase in power consumption, an increase in motion sound of the fan (noise), or the like.

In contrast to this, in the above described electronic apparatus 1a, the pin 39a is provided in the plate 33 of the plug-in unit 30a, and the hole 69a into which the pin 39a is inserted is provided in the plate 63 of the cooling unit using refrigerant 60a at a position corresponding to the pin 39a. Due to the pin 39a and the hole 69a, a gap between the plate 33 and the plate 63 is suppressed, and a decrease in coupled area thereof due to the gap, overheating or damage of the electronic component 31 of the plug-in unit 30a due to that, and stopping of an operation of the electronic apparatus 1a may be suppressed. In this manner, it is possible to obtain the electronic apparatus 1a with excellent performance and a high reliability.

In the electronic apparatus 1a, as exemplified, when a plurality of the pins 39a are provided in the plate 33, and a plurality of the holes 69a are provided in the plate 63, the plates 33 and the plates 63 are positioned at a plurality of portions in facing faces. For this reason, it is possible to increase an effect of suppressing a gap therebetween.

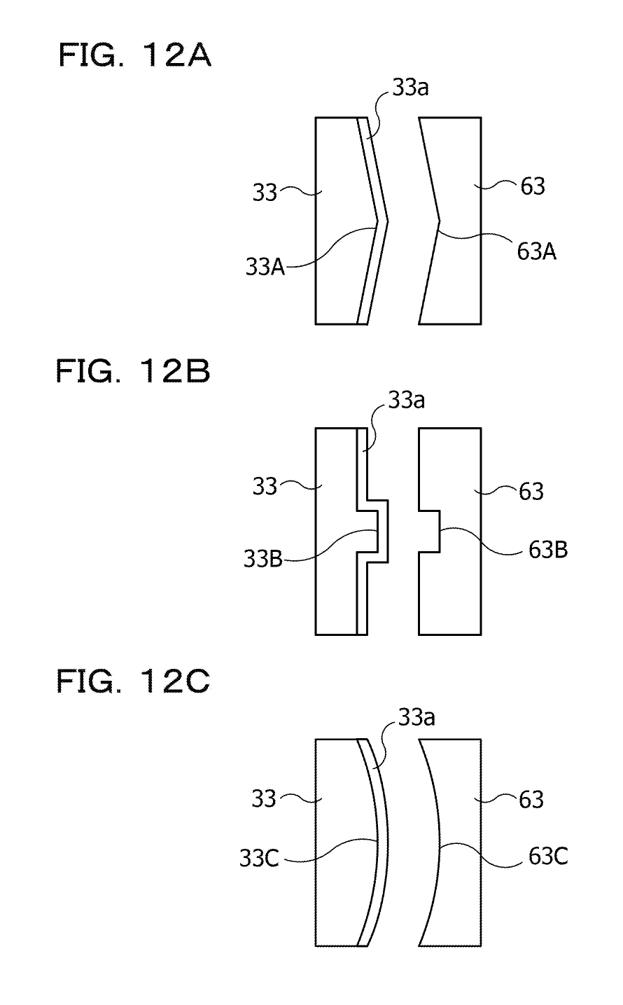

It is also possible to use things illustrated in FIGS. 12A to 12C as the plate 33 and the plate 63 which are coupled.

The FIGS. 12A to 12C are diagrams which illustrate modification examples of the plate. FIGS. 12A to 12C schematically illustrate a section of main portions of an example of the plates which are coupled, respectively.

For example, as illustrated in FIG. 12A, a plate in which a protrusion portion 33A with a V-shaped section is provided is used in the plate 33, and a plate in which a recess portion 63A with a V-shaped section corresponding to the protrusion portion 33A is provided is used in the plate 63. Alternatively, for example, as illustrated in FIG. 12B, a plate in which a protrusion portion 33B with a protrusion section is provided in the plate 33, and a plate in which a recess portion 63B with a recess section corresponding to corresponding to the protrusion portion 33B is provided in the plate 63. Alternatively, for example, as illustrated in FIG. 12C, a plate in which a protrusion portion 33C with a curved protruding face is provided in the plate 33, and a plate in which a recess portion 63C with a curved recessed face corresponding to the protrusion portion 33C is provided in the plate 63. For example, a thermal interface member 33a such as a thermal sheet or thermal grease is provided in the protrusion portions 33A, 33B, and 33C of the plate 33.

In this manner, it is possible to provide a corresponding relief structure in the plate 33 and the plate 63. According to the plate 33 and the plate 63 in which the corresponding relief structure is provided, it is possible to suppress a gap therebetween when being coupled, and increase in coupled area thereof.

Subsequently, a third embodiment is described.

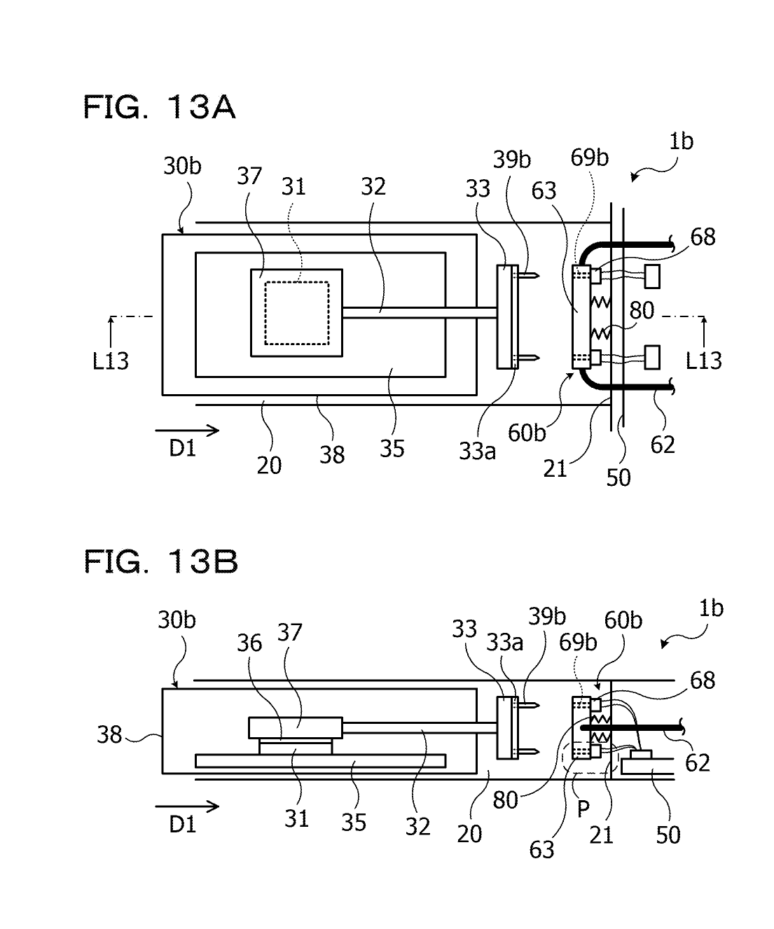

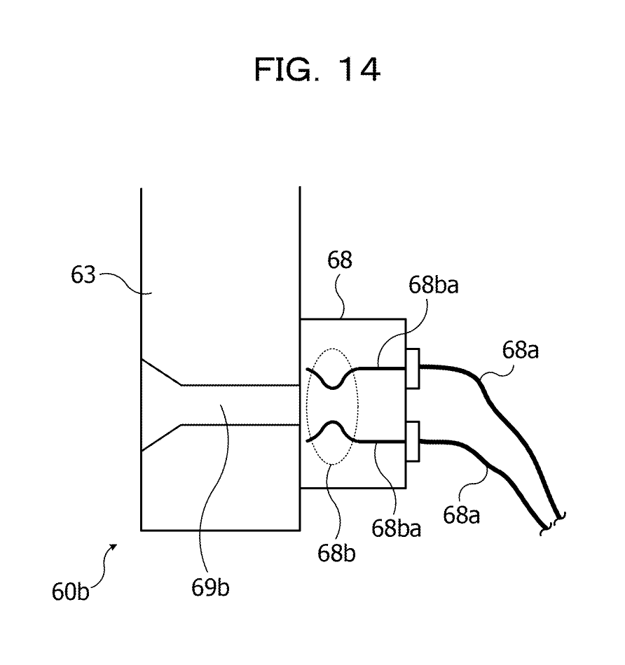

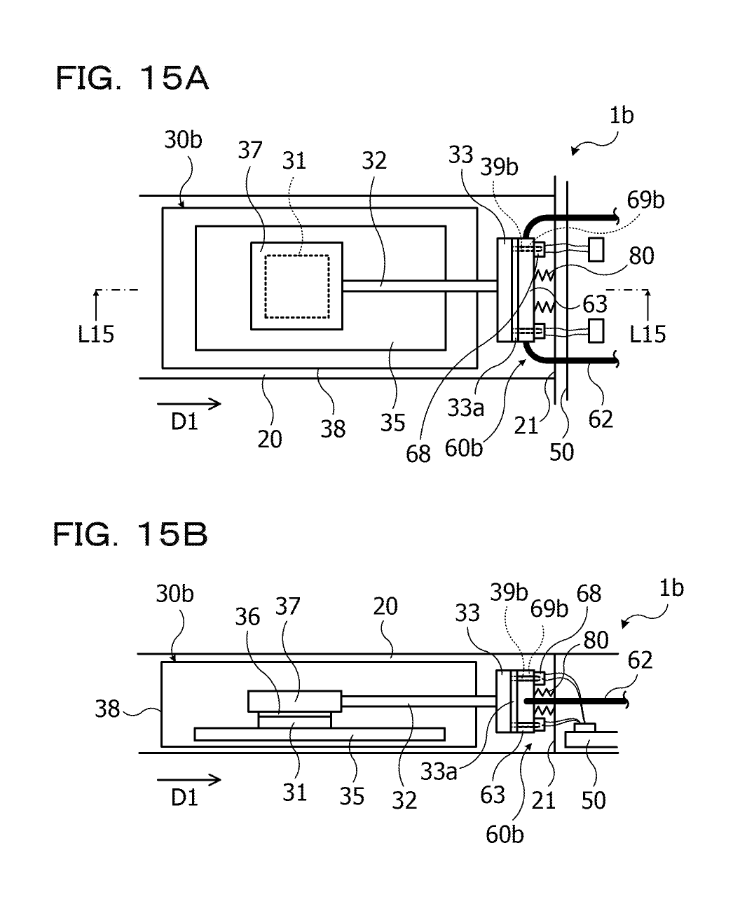

FIGS. 13A, 13B, 14, 15A, and 15B are explanatory diagrams of an electronic apparatus according to the third embodiment. FIG. 13A is a planar schematic view of main portions when inserting the plug-in unit. FIG. 13B is a sectional schematic view of main portions when inserting the plug-in unit. FIG. 14 is a partially enlarged schematic view of a cooling unit using refrigerant. FIG. 15A is a planar schematic view of main portions after inserting the plug-in unit. FIG. 15B is a sectional schematic view of main portions after inserting the plug-in unit. FIG. 13B is a sectional schematic view which is taken along line L13-L13 in FIG. 13A. FIG. 15B is a sectional schematic view which is taken along line L15-L15 in FIG. 15A. FIG. 14 is a partially enlarged schematic view of a P portion in FIG. 13B. In FIGS. 13A, 13B, and 15A and 15B, a connector connection portion of a plug-in unit and a mother board is omitted for convenience.

A plug-in unit 30b illustrated in FIGS. 13A and 13B is provided with a pin 39b protruding in the inserting direction D1 toward the slot 20 is provided in a plate 33 thereof. A cooling unit using refrigerant 60b which is illustrated in FIGS. 13A and 13B is provided with a hole 69b into which the pin 39b is inserted, at a position of the plate 63, corresponding to the pin 39b of the plug-in unit 30b.

Here, the hole 69b of the plate 63 of the cooling unit using refrigerant 60b is provided so as to penetrate the plate 63. An inserting port of the hole 69b for the pin 39b may be expanded in a diameter in a tapered shape toward the inserting port side as illustrated in FIG. 14, so that the pin 39b is easily inserted into the hole 69b. The pin 39b of the plate 33 of the plug-in unit 30b is provided so as to be longer than a thickness of the plate 63 of the cooling unit using refrigerant 60b, that is, a length of the hole 69b which penetrates thereof. A conductor material is used for the pin 39b.

In the plug-in unit 30b and the cooling unit using refrigerant 60b, the plate 33 and the plate 63 are set so as to face each other by suppressing a gap therebetween, when the pin 39b is inserted into the hole 69b corresponding thereto.

As illustrated in FIGS. 13A, 13B, and 14, a connector 68 is further provided in the cooling unit using refrigerant 60b on a face of the plate 63 which is opposite to another face of the plate 63 facing a face of the plate 33 of the plug-in unit 30b. The connector 68 is provided at a position corresponding to the hole 69b of the plate 63, for example. In addition, the connector 68 is coupled to the mother board 50 on the back side of the slot 20 using a cable 68a. The connector 68 is provided with a switch 68b (a pair of conductors 68ba) which is set to ON state by the pin 39b which is inserted into the hole 69b. A signal which denotes an ON state of the switch 68b is transmitted to the mother board 50 through the cable 68a. ON-OFF of the switch 68b of the connector 68 is described later in detail.

In FIGS. 13A and 13B (and 15A and 15B), the plug-in unit 30b in which four pins 39b are provided in the plate 33, and the cooling unit using refrigerant 60b in which four holes 69b are provided in the plate 63 are illustrated as an example. The number of pins 39b and holes 69b is not limited to these. It is possible to provide at least one pin 39b in the plate 33. In addition, it is possible to provide at least one hole 69b in the plate 63. When there are a plurality of the holes 69b, the above described switch 68b is provided in positions of each of the holes 69b.

As illustrated in FIGS. 13A and 13B, the plug-in unit 30b is inserted into the slot 20 in a direction in which the plate 33 faces the inserting direction D1 toward the slot 20. At this time, in the plug-in unit 30b, when a tip end of the pin 39b of the plate 33 is inserted into the hole 69b of the plate 63 of the cooling unit using refrigerant 60b, the pin 39b is guided by the hole 69b, and is inserted into the slot 20. In addition, as illustrated in FIGS. 15A and 15B, in the plug-in unit 30b, the plate 33 (thermal interface member 33a on surface thereof) comes into contact with the plate 63 of the cooling unit using refrigerant 60b, in a state in which the pin 39b is inserted into the hole 69b. In this manner, an electronic apparatus 1b which is illustrated in FIGS. 15A and 15B is obtained.

At this time, in the electronic apparatus 1b, a connection state between the plate 33 and the plate 63 (whether or not plates are coupled) is detected based on ON-Off of the switch 68b of the connector 68 using the pin 39b which is inserted into the hole 69b.

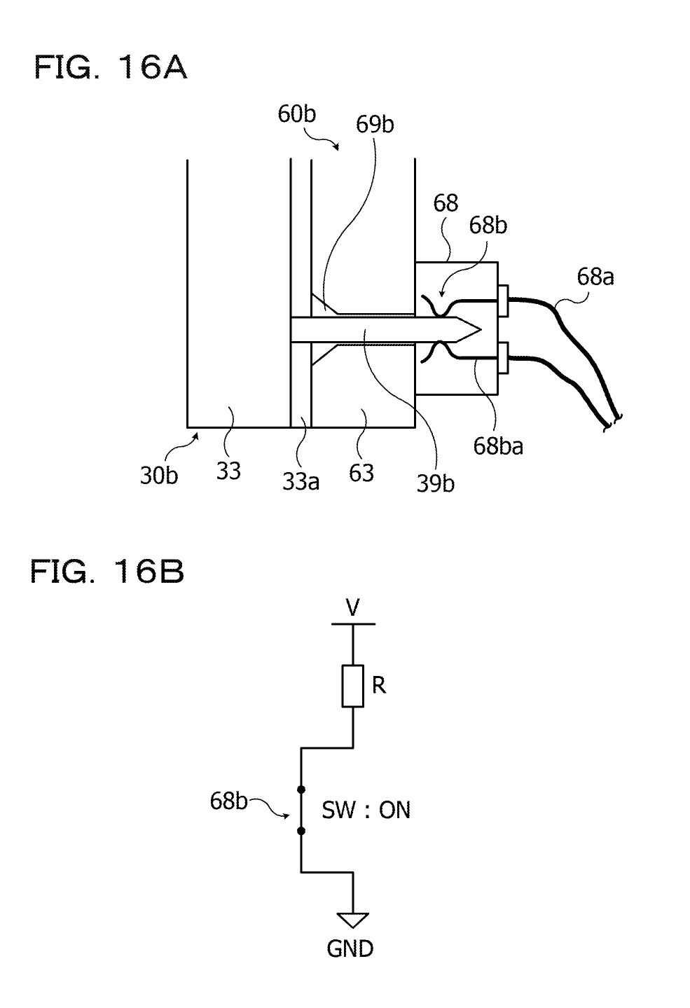

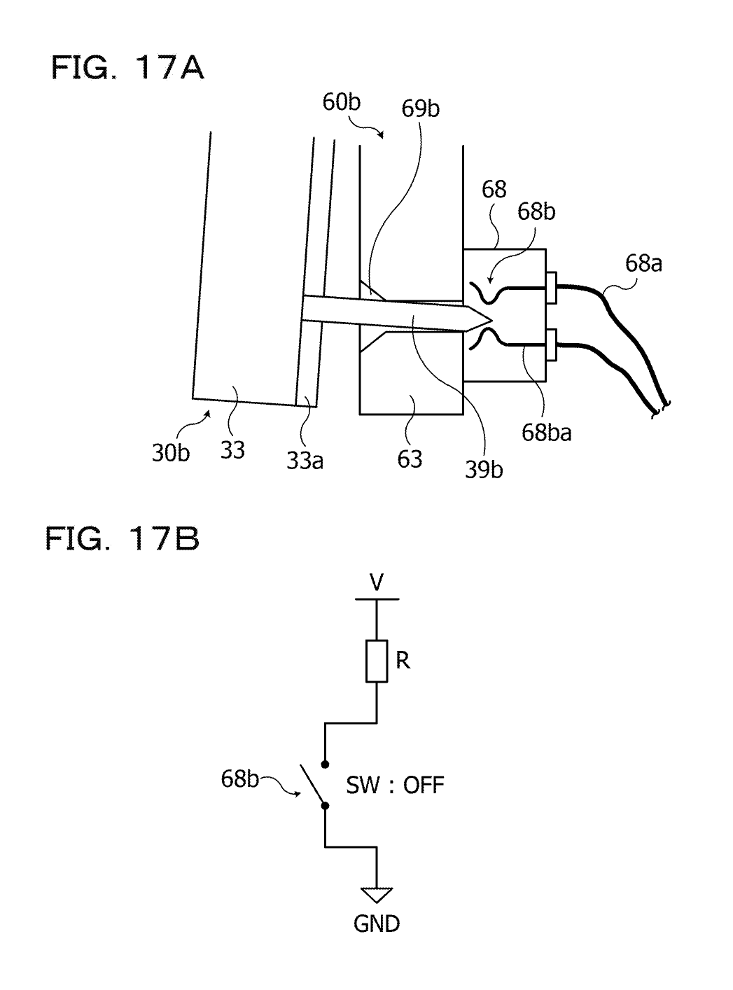

FIGS. 16A, 16B, 17A, and 17B are explanatory diagrams which illustrate detecting of a plate connection state according to a third embodiment. FIGS. 16A and 17A illustrate enlarged sectional schematic views of a switch portion. FIGS. 16B and 17B illustrate an equivalent circuit diagram of the switch portion.

As illustrated in FIGS. 16A and 17A, the connector 68 which is provided in the plate 63 of the cooling unit using refrigerant 60b is provided with the switch 68b. The switch 68b includes the pair of conductors 68ba which is coupled to the cable 68a, and is partially contracted in width. One conductor 68ba is set to a predetermined potential, and the other conductor 68ba is set to a ground potential. An equivalent circuit diagram of a portion including such a switch 68b is illustrated in FIGS. 16B and 17B. As illustrated in FIGS. 16B and 17B, one terminal (one conductor 68ba) of the switch 68b (SW) is coupled to a predetermined voltage V through a resistance R. In addition, the other terminal (the other conductor 68ba) of the switch 68b (SW) is coupled to a ground potential GND.

The pin 39b of the plate 33 of the plug-in unit 30b is inserted into the hole 69b of the plate 63 of the cooling unit using refrigerant 60b in which such a connector 68 is provided, from the inserting port side thereof.

At this time, for example, as illustrated in FIG. 16A, when the pin 39b penetrates the hole 69b, and is inserted into the connector 68 again, a portion between the pair of conductors 68ba of the switch 68b is short-circuited by the pin 39b for which a conductor material is used. In this manner, as illustrated in FIGS. 16A and 16B, the switch 68b of the connector 68 is turned on (SW:ON).

In the plug-in unit 30b and the cooling unit using refrigerant 60b, a configuration of the pin 39b, the hole 69b, and the switch 68b (size, or the like) is set in advance so that the switch 68b is turned on by the pin 39b when the pin 39b is inserted into the hole 69b in a state in which the plate 33 and the plate 63 come into close contact. By setting in this manner, as illustrated in FIGS. 16A and 16B, it is possible to detect that the plate 33 and the plate 63 come into close contact, and are properly coupled without a connection failure, when the switch 68b of the connector 68 is turned on.

Meanwhile, as illustrated in FIG. 17A, when the plate 33 and the plate 63 do not come into close contact, the pin 39b does not penetrate the hole 69b, or does not reach the switch 68b of the connector 68 even when the pin 39b penetrates the hole 69b. For this reason, in the switch 68b, a portion between the pair of conductors 68ba is not short-circuited by the pin 39b, and is turned off (SW:OFF) as illustrated in FIGS. 17A and 17B. In this manner, it is possible to detect that the plate 33 and the plate 63 do not come into close contact, and a connection failure occurs when the switch 68b of the connector 68 is turned off.

It is preferable that a plurality of pins 39b and a plurality of holes 69b corresponding thereto be provided in the plate 33 and the plate 63, respectively, and the switch 68b be provided in each hole 69b. By doing that, it is possible to more accurately detect adhesion between the plate 33 and the plate 63, and a connection state such as an inclination of the other plate to one plate, or a gap in a face direction, based on an ON state or an OFF state of the switch 68b group.

The signal denoting the ON state of the switch 68b is transmitted to the mother board 50 from the connector 68 through the cable 68a. An output unit which outputs information which is generated based on the signal transmitted from the connector 68 to the mother board 50 is provided in the plug-in unit 30b which is coupled to the mother board 50 using the connector, or the electronic apparatus 1b in which the plug-in unit is inserted.

For example, as such an output unit, it is possible to provide a lamp which is lighted when the switch 68b is turned on, in the plug-in unit 30b or the electronic apparatus 1b, or a lamp which is lighted using a different color at a time of an ON state and an OFF state of the switch 68b. Alternatively, it is possible to provide an alarm generation unit which generates an alarm when the switch 68b is not turned on, in the plug-in unit 30b or the electronic apparatus 1b.

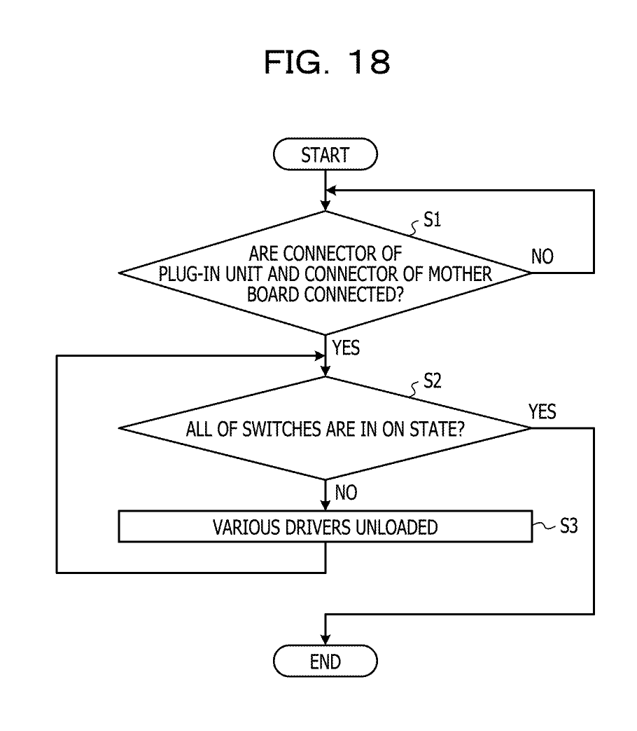

A flow of alarm generating processing when the alarm generation unit is provided as an example of the output unit is illustrated in FIG. 18.

FIG. 18 is a diagram which illustrates an example of a flow of the alarm generating processing according to the third embodiment.

Here, a case in which a plurality of groups of the pin 39b and hole 69b, which are corresponding to each other, and the switch 68b are provided is exemplified.

First, the processor (electronic component 40) mounted on the mother board 50 determines whether or not a connection between the connector of the plug-in unit 30b which is inserted into the slot 20 and the connector of the mother board 50 (for example, connection between connector 34 and connector 54 illustrated in FIGS. 6B and 6C) is performed (step S1).

When it is determined that the connection between the plug-in unit 30b and the mother board 50 is performed (Yes in step S1), the processor determines whether or not all of the switch 68b groups are turned on (step S2).

Here, as described in FIGS. 16A and 16B, when the pin 39b of the plate 33 of the plug-in unit 30b is inserted into the connector 68 again from the hole 69b of the plate 63 of the cooling unit using refrigerant 60b, the switch 68b is turned on. As described in FIGS. 17A and 17B, when the pin 39b is not inserted into the connector 68, the switch 68b is an OFF state. When the pin 39b is inserted so that all of the switch 68b groups are turned on, the plate 33 and the plate 63 are coupled with high adhesion.

In step S2, when it is determined that all of the switch 68b groups are turned on (Yes in step S2), the processor ends the processing without generating an alarm. On the other hand, when it is determined that even one switch is not turned on (No in step S2), the processor generates information (instruction) denoting a generation of alarm, and causes the alarm generation unit to generate an alarm (step S3).

The alarm generation unit is a circuit which generates an alarm by receiving information which is generated by the processor based on a signal denoting an ON state of the switch 68b, and it is possible to provide the alarm generation unit on the mother board 50 of the electronic apparatus 1b, or the circuit board 35 of the plug-in unit 30b.

When the hybrid cooling method in which refrigerant cooling using the cooling unit using refrigerant 60b, and air cooling using the fan unit are used is adopted in the electronic apparatus 1b, the plug-in unit 30b may be cooled down by performing a control of raising the number of rotations of the fan, along with a generation of an alarm.

An operator who inserts the plug-in unit 30b into the slot 20 may know whether or not the plug-in unit 30b is properly inserted into the slot 20, depending on whether or not there is the above described generation of alarm. When there is a generation of an alarm, the operator may check an insertion state of the plug-in unit 30b which is inserted into the slot 20, or perform an operation of extracting the inserted plug-in unit 30b, or reinserting thereof.

Here, the case in which the plurality of groups of the pin 39b and hole 69b which are corresponding, and the switch 68b are provided is exemplified. On the other hand, even when only one group of the pin 39b and hole 69b which are corresponding, and the switch 68b is provided, it is possible to generate an alarm, similarly. That is, in step S2, when the switch 68b is not turned on, an alarm is caused to be generated.

In the electronic apparatus 1b in which the plug-in unit 30b is inserted into the slot 20, the plate 63 of the cooling unit using refrigerant 60b is pressed by the plate 33 of the plug-in unit 30b. In addition, the plate 63 is urged to the plate 33 side by the damper 80. In this manner, a tolerance which may be present in the cooling unit using refrigerant 60b and the plug-in unit 30b is absorbed. In addition, by suppressing a gap between the plate 33 and the plate 63 using the above described pin 39b, hole 69b, and switch 68b, it is possible to obtain the electronic apparatus 1b which is coupled with high adhesion.

In the electronic apparatus 1b, it is possible to detect a connection failure between the plate 33 and the plate 63, and perform a connection with high adhesion between the plate 33 and the plate 63. According to such an electronic apparatus 1b, heat transferring efficiency between the plate 63 and the plate 33 increases, and the electronic component 31 of the plug-in unit 30b is efficiently cooled down. For this reason, it is possible to efficiently suppress overheating of the electronic component, and a damage or deterioration in performance due to overheating. In this manner, the electronic apparatus 1b with excellent performance and high reliability is obtained.

Subsequently, a fourth embodiment is described.

The electronic apparatuses 1, 1a, 1b, and the like, which are described in the first to third embodiments are mounted on a rack or a housing, for example. Here, such forms are described as the fourth embodiment.

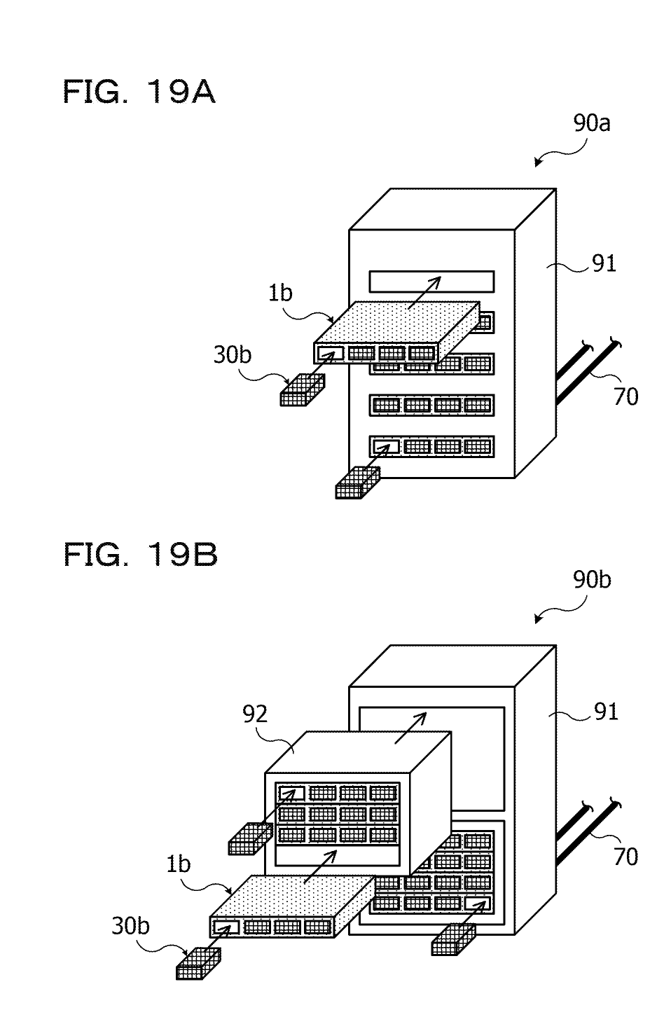

FIGS. 19A and 19B are diagrams which illustrate an example of an electronic apparatus according to the fourth embodiment. FIGS. 19A and 19B schematically illustrate a perspective view of main portions of an example of an electronic device, respectively.

An electronic device 90a illustrated in FIG. 19A has a structure in which a plurality of flat plate-shaped electronic apparatuses, for example, the electronic apparatus 1b which is described in the third embodiment, are mounted on a rack 91 in a stacked shape. In a group of the electronic apparatuses 1b which is mounted on the rack 91, electronic apparatuses which have functions different from each other may be included.

One, or a plurality of plug-in units 30b (plurality of plug-in units 30b are exemplified in FIG. 19A) are inserted into each electronic apparatus 1b of the electronic device 90a. In this case, the electronic apparatus 1b into which one, or a plurality of the plug-in units 30b are inserted maybe mounted on the rack 91. Alternatively, one, or a plurality of plug-in units 30b may be inserted into the electronic apparatus 1b which is mounted on the rack 91.

A plurality of flat plate-shaped electronic apparatuses, for example, the electronic apparatus 1b which is described in the third embodiment is accommodated in a housing 92 of the electronic device 90b which is illustrated in FIG. 19B. In addition, the electronic device 90b has a structure in which the housing 92 is mounted on the rack 91 in a stacked form. Electronic devices which have functions different from each other may be included in a group of the electronic apparatuses 1b which is accommodated in the housing 92. A set of a group of the electronic apparatuses 1b which exhibits a predetermined function in cooperation is accommodated in each housing 92, for example.

One, or a plurality of the plug-in units 30b (plurality of plug-in units 30b are exemplified in FIG. 19B) are inserted into each electronic apparatus 1b of the electronic device 90b. In this case, the electronic apparatus 1b into which one, or a plurality of the plug-in units 30b are inserted may be accommodated in the housing 92. Alternatively, one, or a plurality of the plug-in units 30b may be inserted into the electronic apparatus 1b which is accommodated in the housing 92. Alternatively, one, or a plurality of the plug-in units 30b may be inserted into the electronic apparatus 1b which is accommodated in the housing 92 which is mounted on the rack 91.

The refrigerant pipe 70 (sending pipe and returning pipe) from a cooling tower is coupled to the electronic devices 90a and 90b. The refrigerant pipe 70 is coupled to the electronic apparatus 1b (pipe 62 of cooling unit using refrigerant 60b thereof) which is mounted on the electronic devices 90a and 90b.

As described above, in the electronic apparatus 1b, the plate 33 of the plug-in unit 30b is coupled to the plate 63 of the cooling unit using refrigerant 60b with high adhesion by suppressing a gap therebetween. For this reason, the electronic component 31 which generates heat is efficiently cooled down. In this manner, it is possible to suppress overheating of the electronic component 31, a damage or deterioration in performance of the electronic component 31, the electronic apparatus 1b, and the electronic devices 90a and 90b due to overheating of the electronic component 31.

In addition, in the electronic apparatus 1b, the plug-in unit 30b is separated from the refrigerant flow path of the cooling unit using refrigerant 60b (and refrigerant pipe 70 coupled to cooling tower). For this reason, it is desirable to stop cooling by the cooling unit using refrigerant 60b on the mother board 50 side, even when the plug-in unit 30b is inserted or extracted with respect to the electronic apparatus 1b which is mounted on the rack 91. It is possible to perform inserting or extracting of the plug-in unit 30b with respect to the electronic apparatus 1b without stopping cooling by the cooling unit using refrigerant 60b, and operations of the electronic apparatus 1b, and the electronic devices 90a and 90b. This is a great merit when the electronic apparatus 1b is a communication device which is operated all the time.

Here, as the electronic apparatus, the electronic apparatus 1b which is described in the third embodiment was exemplified. However, it is possible to obtain the electronic devices 90a and 90b, similarly, using the electronic apparatus 1 which is described in the first embodiment, or the electronic apparatus 1a which is described in the second embodiment. Also in this case, it is possible to obtain the same effect. That is, when the plate 33 of the plug-in units 30 and 30a and the plate 63 of the cooling units using refrigerant 60 and 60a are coupled, it is possible to suppress overheating of the electronic component 31, and a damage or deterioration in performance of the electronic component 31, the electronic apparatuses 1, 1a, and the electronic devices 90a and 90b due to overheating of the electronic component 31. In addition, it is possible to perform inserting or extracting of the plug-in units 30 and 30a with respect to the electronic apparatuses 1 and 1a, without stopping cooling down by the cooling units using refrigerant 60 and 60a, and operations of the electronic apparatuses 1, 1a, and the electronic devices 90a and 90b.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic apparatus comprising:
a slot;
a first electronic component inserted into the slot;
a heat pipe coupled to the first electronic component;
a first plate coupled to the heat pipe, and has a heat transferring face facing an insertion direction of the slot;
a second plate which is provided in the slot, faces the first plate, and has a heat transferring face with which the first plate comes into contact; and
a pipe coupled to the second plate, and in which refrigerant circulates.

2. The electronic apparatus according to claim 1, further comprising:
a damper configured to urge the second plate to the first plate side.

3. The electronic apparatus according to claim 1, further comprising:
a pin provided in the first plate, and protrudes to the second plate side; and
a hole provided at a position corresponding to the pin of the second plate, and into which the pin is inserted.

4. The electronic apparatus according to claim 3, further comprising:
a switch configured to be turned on by the pin inserted into the hole.

5. The electronic apparatus according to claim 4,
wherein the switch generates an alarm when in an OFF state.

6. The electronic apparatus according to claim 1, further comprising:
a circuit board that is electrically coupled to the first unit inserted into the slot,
wherein the pipe of the second unit is disposed to pass through a position of a second electronic component mounted on the circuit board.

7. The electronic apparatus according to claim 1, further comprising:
a cooling plate provided on the first electronic component,
wherein the heat pipe is provided to extend in the insertion direction from the cooling plate.

8. The electronic apparatus according to claim 7,
wherein the heat pipe is disposed in such a way that one end of the heat pipe is coupled to the cooling plate.

9. The electronic apparatus according to claim 7,
wherein the heat pipe is disposed to run through the inside of the cooling plate.

10. The electronic apparatus according to claim 1, further comprising:
an elastic tube that is provided on a slot side of the pipe, and is coupled to the second plate.

11. The electronic apparatus according to claim 10,
wherein the tube is formed of tetrafluoroethylene-hexafluoropropylene copolymer (FEP).

12. A cooling method which is processed by an electronic apparatus including a slot, a first electronic component inserted into the slot, a heat pipe coupled to the first electronic component, a first plate coupled to the heat pipe, and has a heat transferring face facing an insertion direction of the slot, a second plate provided in the slot, faces the first plate, and has a heat transferring face with which the first plate comes into contact, and a pipe coupled to the second plate, and in which refrigerant circulates, the cooling method comprising:
transmitting heat generated in the electronic component to the second plate through the heat pipe and the first plate; and
removing the transmitted heat by using the refrigerant which circulates in the pipe.
